(19) United States
(12) Patent Application Publication
(10) Pub. No.: US 2026/0040659 A1
(43) Pub. Date: Feb. 5, 2026

(54) SEMICONDUCTOR DEVICE

(71) Applicant: DENSO CORPORATION, Kariya-city (JP)

(72) Inventors: Takashi KUNO, Kariya-city (JP); Toshiki KAWASE, Kariya-city (JP); Eisuke ISHIKAWA, Kariya-city (JP)

(21) Appl. No.: 19/354,094

(22) Filed: Oct. 9, 2025

Related U.S. Application Data
(63) Continuation of application No. PCT/JP2024/002508, filed on Jan. 26, 2024.

(30) Foreign Application Priority Data
Apr. 18, 2023 (JP) 2023-067968

(51) Int. Cl. H10D 84/00; H10D 8/00; H10D 12/00; H10D 62/10; H10D 62/60

(52) U.S. Cl. CPC H10D 84/161; H10D 8/422; H10D 12/481; H10D 62/124; H10D 62/60

(57) ABSTRACT

A semiconductor substrate of a reverse conducting IGBT has a first conductivity type buffer layer disposed between a collector layer and a drift layer. The buffer layer has a first buffer layer provided in the IGBT region and a second buffer layer provided in the boundary region. The peak concentration of the first conductivity type impurity in the second buffer layer is higher than that in the first buffer layer.

### CROSS REFERENCE TO RELATED APPLICATION

The present application is a continuation application of International Patent Application No. PCT/JP2024/002508 filed on Jan. 26, 2024, which designated the U.S. and claims the benefit of priority from Japanese Patent Application No. 2023-067968 filed on Apr. 18, 2023. The entire disclosures of all of the above applications are incorporated herein by reference.

### TECHNICAL FIELD

The present disclosure relates to a semiconductor device.

### BACKGROUND

A semiconductor device such as a reverse conducting Insulated Gate Bipolar Transistor (reverse conducting IGBT) has a semiconductor substrate. The reverse conducting IGBT has an IGBT region in which an IGBT structure is provided, and a diode region in which a diode structure is provided. The diode structure is connected in anti-parallel to the IGBT structure and can operate as a freewheeling diode during recovery operation.

### SUMMARY

A semiconductor device, such as a reverse conducting IGBT, includes a semiconductor substrate having an IGBT region, a diode region, and a boundary region located between the IGBT region and the diode region. The semiconductor device has a lower electrode provided on a lower surface of the semiconductor substrate, and an upper electrode provided on an upper surface of the semiconductor substrate. The semiconductor substrate includes: a drift layer of a first conductivity type provided across the IGBT region, the diode region, and the boundary region; a base layer of a second conductivity type provided across the IGBT region, the diode region, and the boundary region and disposed above the drift layer; an emitter layer of a first conductivity type provided in the IGBT region, disposed above the base layer, and in contact with the upper electrode; a collector layer of a second conductivity type provided in the IGBT region and the boundary region, disposed below the drift layer, and in contact with the lower electrode; a cathode layer of a first conductivity type provided in the diode region, disposed below the drift layer, and in contact with the lower electrode; and a buffer layer of a first conductivity type disposed between the collector layer and the drift layer. The buffer layer has a concentration of a first conductivity type impurity higher than a concentration of a first conductivity type impurity in the drift layer. The buffer layer includes a first buffer layer provided in the IGBT region and a second buffer layer provided in the boundary region. The peak concentration of the first conductivity type impurity in the second buffer layer is higher than the peak concentration of the first conductivity type impurity in the first buffer layer.

### BRIEF DESCRIPTION OF DRAWINGS

FIG. 1 is a schematic plan view of a semiconductor device according to an embodiment, illustrating a planar layout for explaining an IGBT region, a diode region, and a boundary region.

FIG. 2 is a schematic cross-sectional view taken along line II-II in FIG. 1 to illustrate the IGBT region, the diode region, and the boundary region defined in an element region of the semiconductor device of the embodiment.

FIG. 3 is a schematic cross-sectional view illustrating a semiconductor device of a modification to show an IGBT region, a diode region, and a boundary region, corresponding to line II-II in FIG. 1.

FIG. 4 is a schematic cross-sectional view illustrating a semiconductor device of a modification to show an IGBT region, a diode region, and a boundary region, corresponding to line II-II in FIG. 1.

FIG. 5 is a schematic cross-sectional view illustrating a semiconductor device of a modification to show an IGBT region, a diode region, and a boundary region, corresponding to line II-II in FIG. 1.

### DETAILED DESCRIPTION

A semiconductor device such as a reverse conducting Insulated Gate Bipolar Transistor (reverse conducting IGBT) has a semiconductor substrate. The reverse conducting IGBT has an IGBT region in which an IGBT structure is provided, and a diode region in which a diode structure is provided. The diode structure is connected in anti-parallel to the IGBT structure and can operate as a freewheeling diode during recovery operation.

In the semiconductor device, during recovery operation, holes are injected obliquely from the p-type base layer in the IGBT region toward the n-type cathode layer in the diode region. When the amount of holes injected obliquely from the p-type base layer toward the n-type cathode layer increases, the recovery current increases, and the recovery loss increases. For this reason, a boundary region is provided between the IGBT region and the diode region in the semiconductor device. In the boundary region, a p-type collector layer is formed extending from the IGBT region. As a result, the diode structure is not formed in the boundary region, and the amount of holes injected obliquely from the p-type base layer toward the n-type cathode layer during recovery operation is suppressed.

If a p-type collector layer is provided in the boundary region, holes are injected from the p-type collector layer in the boundary region toward the n-type drift layer in the boundary region when the IGBT structure is on. When the IGBT structure is turned off, the holes injected into the drift layer in the boundary region move in an oblique direction toward the p-type base layer of the IGBT region and are discharged through the p-type base layer. This increases the time taken for the holes to be discharged, raising concerns that an increase in tail current will result in increased switching losses.

The present specification provides a semiconductor device, for suppressing an increase in switching loss, having a boundary region between an IGBT region and a diode region in a reverse conducting IGBT.

A semiconductor device disclosed in this specification, such as a reverse conducting IGBT, includes a semiconductor substrate having an IGBT region, a diode region, and a boundary region located between the IGBT region and the diode region. The semiconductor device has a lower electrode provided on a lower surface of the semiconductor substrate, and an upper electrode provided on an upper surface of the semiconductor substrate. The semiconductor substrate includes: a drift layer of a first conductivity type provided across the IGBT region, the diode region, and the boundary region; a base layer of a second conductivity type provided across the IGBT region, the diode region, and the boundary region and disposed above the drift layer; an emitter layer of a first conductivity type provided in the IGBT region, disposed above the base layer, and in contact with the upper electrode; a collector layer of a second conductivity type provided in the IGBT region and the boundary region, disposed below the drift layer, and in contact with the lower electrode; a cathode layer of a first conductivity type provided in the diode region, disposed below the drift layer, and in contact with the lower electrode; and a buffer layer of a first conductivity type disposed between the collector layer and the drift layer. The buffer layer has a concentration of a first conductivity type impurity higher than a concentration of a first conductivity type impurity in the drift layer. The buffer layer includes a first buffer layer provided in the IGBT region and a second buffer layer provided in the boundary region. The peak concentration of the first conductivity type impurity in the second buffer layer is higher than the peak concentration of the first conductivity type impurity in the first buffer layer. The “disposed above” and “disposed below” are descriptions that specify only the positional relationship between the two semiconductor layers in the vertical direction of the semiconductor substrate. For example, the two semiconductor layers may be disposed to be in contact with each other, or another semiconductor layer may be interposed between the two semiconductor layers. Moreover, the terms “first conductivity type” and “second conductivity type” are used to specify that they are different conductivity types. For example, the “first conductivity type” may be n-type and the “second conductivity type” may be p-type.

In the reverse conducting IGBT, the collector layer is provided in the boundary region of the semiconductor substrate. Therefore, the amount of carriers injected obliquely from the base layer of the IGBT region toward the cathode layer of the diode region during recovery operation is suppressed. Furthermore, in the reverse conducting IGBT, the second buffer layer in which the concentration of the first conductivity type impurity is adjusted to be high is provided in the boundary region of the semiconductor substrate. Therefore, when the IGBT structure in the IGBT region is on, the amount of carriers injected into the drift layer in the boundary region is suppressed. Therefore, in the reverse conducting IGBT, an increase in switching loss is suppressed.

A semiconductor device of this embodiment will be described below with reference to the drawings. For the purpose of clarity, in the drawings, only one of components repeatedly arranged is labeled with a reference symbol, and the other components are not labeled with the reference symbol.

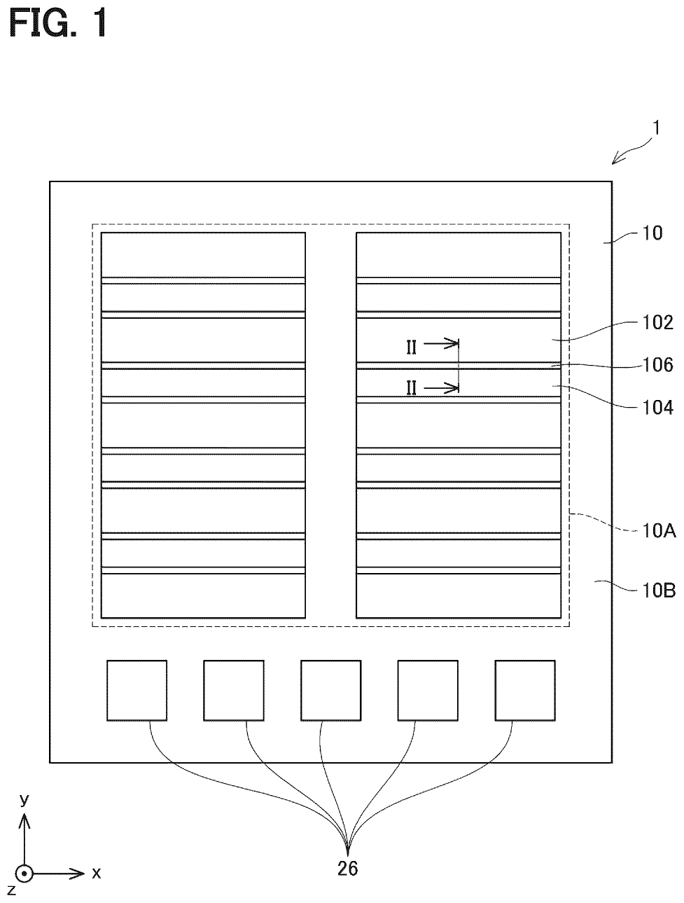

FIG. 1 is a schematic plan view showing a layout of a semiconductor device 1 according to the present embodiment. The semiconductor device 1 is a reverse conducting IGBT, and is manufactured by using a semiconductor substrate 10. The semiconductor substrate 10 has an element region 10A and a termination region 10B located around the element region 10A. The element region 10A of the semiconductor substrate 10 has an IGBT region 102 in which an IGBT structure is provided, a diode region 104 in which a diode structure is provided, and a boundary region 106 located between the IGBT region 102 and the diode region 104. When viewed from a direction perpendicular to the top surface of the semiconductor substrate 10 (hereinafter referred to as “when the semiconductor substrate 10 is viewed in a plan view”), the IGBT regions 102 and the diode regions 104 are arranged alternately within the element region 10A along one direction (the y direction in this example). A termination breakdown structure such as a guard ring is formed in an area of the semiconductor substrate 10 that corresponds to the termination region 10B. Plural small signal pads 26 are provided on the upper surface of the semiconductor substrate 10 in an area corresponding to the termination region 10B. The small signal pad 26 may be, for example, a gate pad for inputting a gate signal, a temperature sense pad for outputting a temperature sense signal, and a current sense pad for outputting a current sense signal.

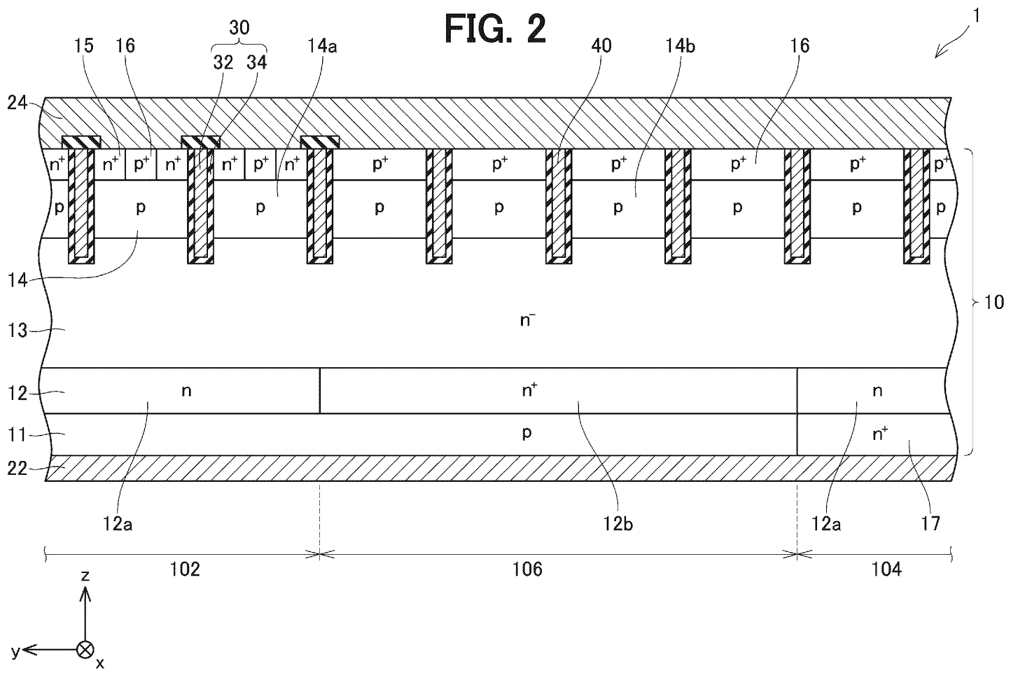

FIG. 2 schematically shows a cross-sectional view taken along line II-II of FIG. 1. As shown in FIG. 2, the semiconductor device 1 includes: the semiconductor substrate 10 which is a silicon substrate; a collector electrode 22 (an example of a lower electrode) provided to cover the lower surface of the semiconductor substrate 10; an emitter electrode 24 (an example of an upper electrode) provided to cover the upper surface of the semiconductor substrate 10; trench gates 30 provided in an upper layer of the semiconductor substrate 10; and dummy trench gates 40 provided in an upper layer of the semiconductor substrate 10.

The semiconductor substrate 10 has a p-type collector layer 11, an n-type buffer layer 12, an n-type drift layer 13, a p-type base layer 14, n+ type emitter layers 15, p+ type contact layers 16, and an n+ type cathode layer 17.

The collector layer 11 is provided in a range corresponding to the IGBT region 102 and the boundary region 106 in the lower layer of the semiconductor substrate 10, at a position exposed from the lower surface of the semiconductor substrate 10. The collector layer 11 is in ohmic contact with the collector electrode 22 that covers the lower surface of the semiconductor substrate 10. The collector layer 11 is formed by ion-implanting p-type impurity toward the lower surface of the semiconductor substrate 10 using an ion implantation technique. The collector layer 11 is formed by multi-stage ion implantation and may have plural peak concentrations in the thickness direction of the semiconductor substrate 10. The p-type impurity is not particularly limited, but may be, for example, boron. The peak concentration of the p-type impurity contained in the collector layer 11 is not particularly limited, but may be, for example, 1×10¹⁶ cm⁻³ to 1×10¹⁸ cm⁻³.

The buffer layer 12 is provided across the IGBT region 102, the boundary region 106, and the diode region 104 of the semiconductor substrate 10. The buffer layer 12 is provided between the collector layer 11 and the drift layer 13 in the IGBT region 102 and the boundary region 106. The buffer layer 12 separates the collector layer 11 and the drift layer 13 from each other. The lower surface of the buffer layer 12 is in contact with the collector layer 11 and the upper surface of the buffer layer 12 is in contact with the drift layer 13. The buffer layer 12 is provided between the cathode layer 17 and the drift layer 13 in the diode region 104 to separate the cathode layer 17 from the drift layer 13. The lower surface of the buffer layer 12 is in contact with the cathode layer 17 and the upper surface of the buffer layer 12 is in contact with the drift layer 13. Alternatively, the buffer layer 12 may not be provided in the diode region 104. The buffer layer 12 has a higher concentration of n-type impurity than the drift layer 13. The buffer layer 12 is formed by ion-implanting n-type impurity toward the lower surface of the semiconductor substrate 10 using an ion implantation technique. The n-type impurity is not particularly limited, but may be, for example, phosphorus. The peak concentration of the n-type impurity contained in the buffer layer 12 is not particularly limited, but may be, for example, 1×10¹⁵ cm⁻³ to 1×10¹⁸ cm⁻³.

In this example, the buffer layer 12 includes a first buffer layer 12a and a second buffer layer 12b. The first buffer layer 12a of the buffer layer 12 is provided in an area corresponding to the IGBT region 102 and the diode region 104 of the semiconductor substrate 10. In this example, the first buffer layer 12a is provided over an entirety of the IGBT region 102 and the diode region 104. The second buffer layer 12b of the buffer layer 12 is provided in a range corresponding to the boundary region 106 of the semiconductor substrate 10. In this example, the second buffer layer 12b is provided over the entire boundary region 106. The peak concentration of the n-type impurity in the second buffer layer 12b is higher than the peak concentration of the n-type impurity in the first buffer layer 12a. In this manner, the peak concentration of the n-type impurity in the buffer layer 12 is adjusted to be high in the range corresponding to the boundary region 106.

The drift layer 13 is provided across the IGBT region 102, the boundary region 106, and the diode region 104 of the semiconductor substrate 10. The drift layer 13 is provided between the buffer layer 12 and the base layer 14 to separate the buffer layer 12 and the base layer 14 from each other. The lower surface of the drift layer 13 is in contact with the buffer layer 12 and the upper surface of the drift layer 13 is in contact with the base layer 14. The drift layer 13 is a remnant of the semiconductor substrate 10 after the other semiconductor layers have been formed. The peak concentration of the n-type impurity contained in the drift layer 13 is not particularly limited, but may be, for example, 1×10¹³ cm⁻³ to 1×10¹⁵ cm⁻³.

The base layer 14 is provided across the IGBT region 102, the boundary region 106, and the diode region 104 of the semiconductor substrate 10. The base layer 14 is provided in the IGBT region 102 between the drift layer 13 and the emitter layer 15 and between the drift layer 13 and the contact layer 16. The base layer 14 separates the drift layer 13 from the emitter layer 15 and the contact layer 16. The lower surface of the base layer 14 is in contact with the drift layer 13 and the upper surface of the base layer 14 is in contact with the emitter layer 15 and the contact layer 16. The base layer 14 is provided between the drift layer 13 and the contact layer 16 in the boundary region 106 and the diode region 104 to separate the drift layer 13 and the contact layer 16 from each other. The lower surface of the base layer 14 is in contact with the drift layer 13 and the upper surface of the base layer 14 is in contact with the contact layer 16. The base layer 14 is formed by ion-implanting p-type impurity into the upper surface of the semiconductor substrate 10 using an ion implantation technique. The p-type impurity is not particularly limited, but may be, for example, boron. The peak concentration of the p-type impurity contained in the base layer 14 is not particularly limited, but may be, for example, 1×10¹⁵ cm⁻³ to 1×10¹⁷ cm⁻³.

In this example, the base layer 14 includes a first base layer 14a and a second base layer 14b. The first base layer 14a of the base layer 14 is provided in a range corresponding to the IGBT region 102 of the semiconductor substrate 10. The second base layer 14b of the base layer 14 is provided in a range corresponding to the diode region 104 and the boundary region 106 of the semiconductor substrate 10. The concentration of the p-type impurity in the first base layer 14a is adjusted so that the gate threshold voltage of the trench gate 30 has a desired value. The concentration of the p-type impurity in the second base layer 14b is adjusted in order to control the amount of holes injected during the recovery operation. Therefore, the concentration of p-type impurity in the second base layer 14b is lower than the concentration of p-type impurity in the first base layer 14a.

Each of the emitter layers 15 is partially provided in an area corresponding to the IGBT region 102, at the upper layer of the semiconductor substrate 10, at a position exposed from the upper surface of the semiconductor substrate 10. Each of the emitter layers 15 is in contact with a side surface of the trench gate 30 and is in ohmic contact with the emitter electrode 24 covering the upper surface of the semiconductor substrate 10. Each of the emitter layers 15 is selectively formed in the IGBT region 102 of the semiconductor substrate 10, and is not formed in the diode region 104 and the boundary region 106 of the semiconductor substrate 10. In other words, the area of the semiconductor substrate 10 where the emitter layers 15 are provided becomes the IGBT region 102. The emitter layer 15 is formed by ion-implanting n-type impurity into the upper surface of the semiconductor substrate 10 using an ion implantation technique. The n-type impurity is not particularly limited, but may be, for example, phosphorus. The peak concentration of the n-type impurity contained in each of the emitter layers 15 is not particularly limited, but may be, for example, 1×10¹⁸ cm⁻³ to 1×10²⁰ cm⁻³. In the technology disclosed in this specification, the layout of the emitter layers 15 formed in the upper layer of the semiconductor substrate 10 is not particularly limited, and various layouts can be adopted.

Each of the contact layers 16 is provided partially across the IGBT region 102, the boundary region 106, and the diode region 104 of the semiconductor substrate 10, at a position exposed from the upper surface of the semiconductor substrate 10. Each of the contact layers 16 is in ohmic contact with the emitter electrode 24 covering the upper surface of the semiconductor substrate 10. Each of the contact layers 16 is formed by ion-implanting p-type impurity toward the upper surface of the semiconductor substrate 10 using an ion implantation technique. The p-type impurity is not particularly limited, but may be, for example, boron. The peak concentration of the p-type impurity contained in each of the contact layers 16 is not particularly limited, but may be, for example, 1×10¹⁷ cm⁻³ to 1×10²⁰ cm⁻³. In the technology disclosed in this specification, the layout of the contact layers 16 in the upper layer of the semiconductor substrate 10 is not particularly limited, and various layouts can be adopted.

The cathode layer 17 is provided in a range corresponding to the diode region 104, at the lower layer of the semiconductor substrate 10, at a position exposed from the lower surface of the semiconductor substrate 10. The cathode layer 17 is in ohmic contact with the collector electrode 22 that covers the lower surface of the semiconductor substrate 10. The cathode layer 17 is selectively formed in the diode region 104 of the semiconductor substrate 10, and is not formed in the IGBT region 102 and the boundary region 106 of the semiconductor substrate 10. In other words, an area of the semiconductor substrate 10 where the cathode layer 17 is provided becomes the diode region 104. The cathode layer 17 is formed by ion-implanting n-type impurity toward the lower surface of the semiconductor substrate 10 using an ion implantation technique. The cathode layer 17 may be formed by multi-stage ion implantation and may have plural peak concentrations in the thickness direction of the semiconductor substrate 10. The n-type impurity is not particularly limited, but may be, for example, phosphorus. The peak concentration of the n-type impurity contained in the cathode layer 17 is not particularly limited, but may be, for example, 1×10¹⁸ cm⁻³ to 1×10²⁰ cm⁻³.

Each of the trench gates 30 is provided in a trench formed in an area corresponding to the IGBT region 102 at the upper layer of the semiconductor substrate 10, and has a gate electrode 32 and a gate insulating film 34. The gate electrode 32 is insulated from the semiconductor substrate 10 by the gate insulating film 34, and is insulated from the emitter electrode 24 by the interlayer insulating film. Each of the trench gates 30 penetrates the base layer 14 from the upper surface of the semiconductor substrate 10 to reach the drift layer 13. In this example, the trench gates 30 extend in the x direction, when the semiconductor substrate 10 is viewed in a plan view, and are disposed at intervals from one another in the y direction. That is, when the semiconductor substrate 10 is viewed in a plan view, the trench gates 30 are arranged at intervals from one another along a direction in which the IGBT regions 102 and the diode regions 104 are alternately arranged, to have a striped layout. Alternatively, the trench gates 30 may have other types of layouts.

Each of the dummy trench gates 40 is provided in a trench formed in an area corresponding to the diode region 104 and the boundary region 106, at the upper layer of the semiconductor substrate 10. The dummy trench gates 40 are fabricated in the same manufacturing process as the trench gates 30, and differ from the trench gates 30 in that the interlayer insulating film that insulates the gate electrode 32 and the emitter electrode 24 is removed. The dummy trench gates 40 have the same layout as the trench gates 30. When the dummy trench gate 40 is provided, the electric field concentration in the diode region 104 and the boundary region 106 can be alleviated.

The semiconductor device 1 can control the on/off of a current flowing through the IGBT region 102 from the collector electrode 22 to the emitter electrode 24 based on a gate voltage applied to the gate electrode 32 of the trench gate 30. Furthermore, in the semiconductor device 1, the diode structure formed in the diode region 104 can operate as a freewheeling diode during recovery operation.

During recovery operation in which the diode structure operates, if the amount of holes injected obliquely from the p-type base layer 14 of the IGBT region 102 toward the n-type cathode layer 17 of the diode region 104 increases, the recovery current increases and the recovery loss increases. In the semiconductor device 1, since the collector layer 11 is provided in the boundary region 106, the distance between the p-type base layer 14 in the IGBT region 102 and the n-type cathode layer 17 in the diode region 104 becomes long. Therefore, the amount of holes injected in an oblique direction during recovery operation is suppressed, and the recovery current is suppressed. Therefore, the semiconductor device 1 can have low recovery loss characteristics.

The width of the boundary region 106 measured along the direction connecting the IGBT region 102 and the diode region 104 is adjusted to a size necessary to suppress the amount of holes injected in an oblique direction. The width of the boundary region 106 is not particularly limited, but may be, for example, 0.5 μm or more, and preferably 1.0 μm or more. Furthermore, the width of the boundary region 106 may be larger than the pitch width between the dummy trench gates 40 adjacent to each other. Alternatively, the width of the boundary region 106 may be greater than the thickness of the semiconductor substrate 10. The width of the boundary region 106 may be smaller than twice the thickness of the semiconductor substrate 10 in order to reduce area consumption.

A case will be considered in which the peak concentration of the n-type impurity in the buffer layer 12 is constant across the IGBT region 102, the boundary region 106 and the diode region 104. In this case, the peak concentration of the n-type impurity in the buffer layer 12 is adjusted to allow hole injection from the collector layer 11 when the IGBT structure is on, and to enable the depletion layer extending from the base layer 14 to be stopped when the IGBT structure is off. If the buffer layer 12 is adjusted to such a concentration, holes are injected from the collector layer 11 in the boundary region 106 toward the drift layer 13 in the boundary region 106 when the IGBT structure is turned on. When the IGBT structure is turned off, the holes injected into the drift layer 13 in the boundary region 106 move obliquely toward the p-type base layer 14 in the IGBT region 102 and are discharged through the p-type base layer 14. This increases the time taken for the holes to be discharged, and the tail current increases, resulting in increased switching losses.

In the semiconductor device 1, the second buffer layer 12b in which the peak concentration of the n-type impurity is adjusted to be high is provided in a region of the buffer layer 12 corresponding to the boundary region 106. The second buffer layer 12b, in which the peak concentration of the n-type impurity is adjusted to be high, can function as a hole stopper layer. Therefore, when the IGBT structure is turned on, the amount of holes injected from the collector layer 11 in the boundary region 106 toward the drift layer 13 in the boundary region 106 is suppressed. Therefore, the semiconductor device 1 can have low switching loss characteristics.

If the peak concentration of the n-type impurity in the second buffer layer 12b is higher than the peak concentration of the p-type impurity in the collector layer 11, holes are not substantially injected from the collector layer 11 in the boundary region 106 toward the drift layer 13 in the boundary region 106. In this case, the on-voltage when the IGBT structure is on becomes high. When the peak concentration of the n-type impurity in the second buffer layer 12b is lower than the peak concentration of the p-type impurity in the collector layer 11, the semiconductor device 1 can have low switching loss characteristics while keeping the on-voltage low when the IGBT structure is on.

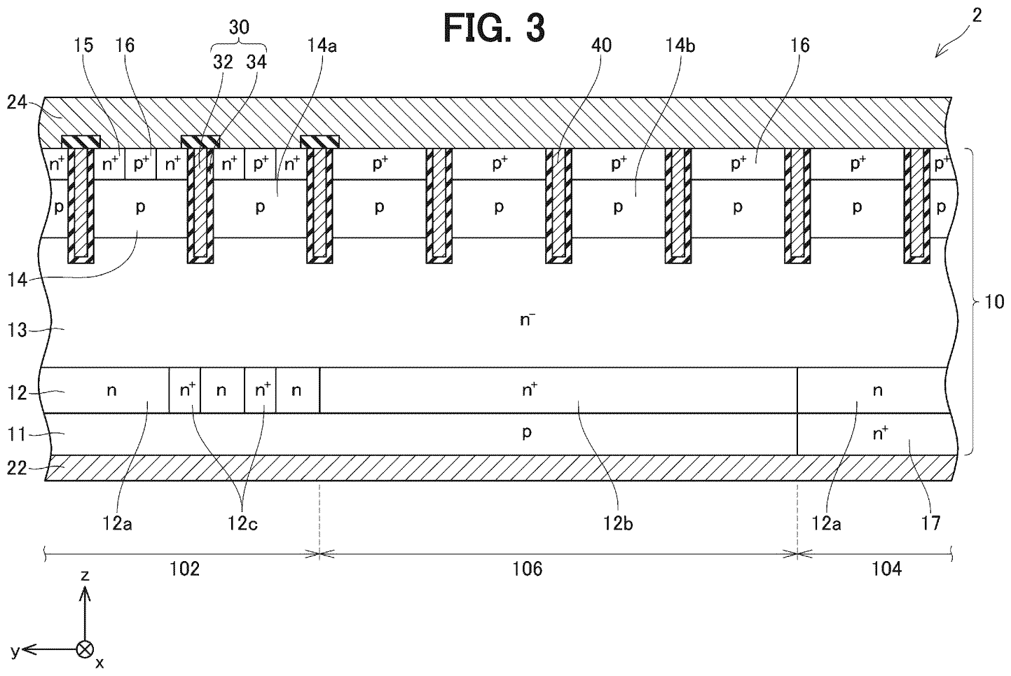

The semiconductor device 1 can be modified as follows. As shown in FIG. 3, in a semiconductor device 2, the buffer layer 12 further includes third buffer layers 12c. Each of the third buffer layers 12c is provided in a region of the buffer layer 12 that corresponds to the IGBT region 102 of the semiconductor substrate 10, in the vicinity of the boundary between the IGBT region 102 and the boundary region 106. The peak concentration of the n-type impurity in each of the third buffer layers 12c is higher than the peak concentration of the n-type impurity in the first buffer layer 12a. The peak concentration of the n-type impurity in each of the third buffer layers 12c may be the same as the peak concentration of the n-type impurity in the second buffer layer 12b. That is, the second buffer layer 12b and the third buffer layer 12c may be formed using a common ion implantation mask.

It is possible to control the on-voltage when the IGBT structure is turned on and to control the switching loss when the IGBT structure is turned off, by adjusting the peak concentration of the n-type impurity in the boundary region 106 of the buffer layer 12. The peak concentration of n-type impurity in the buffer layer 12 within a certain distance from the boundary between the IGBT region 102 and the boundary region 106 toward the IGBT region 102 can also affect the on-voltage when the IGBT structure is turned on and the switching loss when the IGBT structure is turned off. In the semiconductor device 2, the third buffer layers 12c are provided within a range of a predetermined distance from the boundary between the IGBT region 102 and the boundary region 106 toward the IGBT region 102. Therefore, in the semiconductor device 2, the on-voltage when the IGBT structure is turned on and the switching loss when the IGBT structure is turned off can be further improved. The specified distance measured from the boundary between the IGBT region 102 and the boundary region 106 toward the IGBT region 102 is not particularly limited, but may be, for example, 5 μm or less, 4 μm or less, 3 μm or less, 2 μm or less, or 1 μm or less. The specified distance may be equal to or less than the pitch width between the trench gates 30 adjacent to each other. Alternatively, the specified distance may be equal to or less than the thickness of the semiconductor substrate 10.

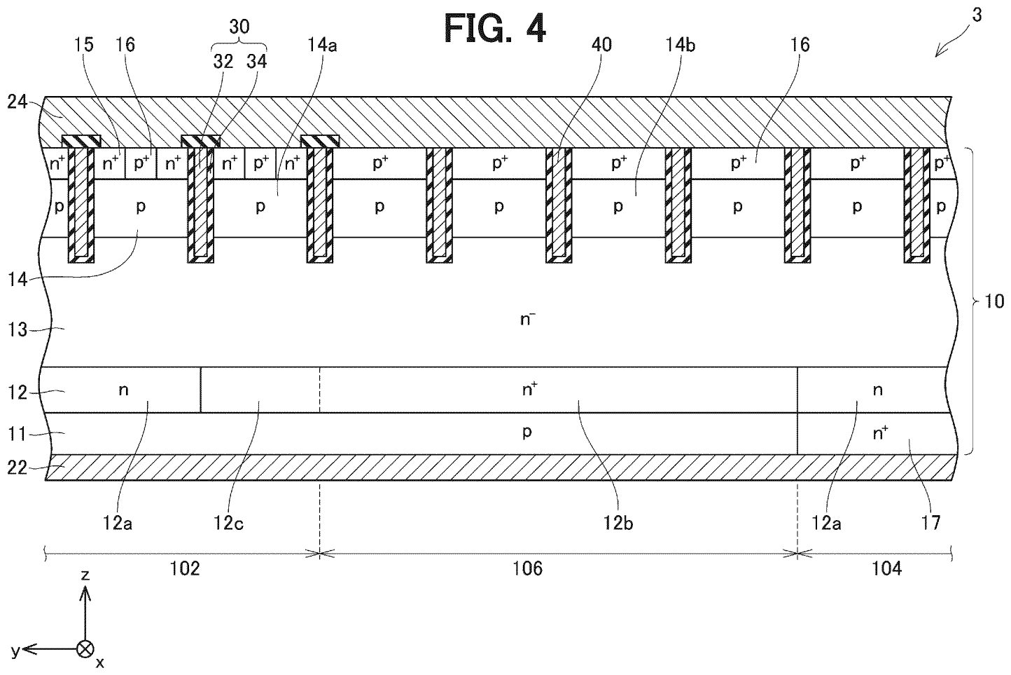

As shown in FIG. 4, the third buffer layer 12c may be adjacent to the second buffer layer 12b at the boundary between the IGBT region 102 and the boundary region 106, in a semiconductor device 3. In this example, the third buffer layer 12c may be formed by the second buffer layer 12b penetrating into the IGBT region 102 from the boundary between the IGBT region 102 and the boundary region 106. The semiconductor device 3 can achieve the same effects as the semiconductor device 2.

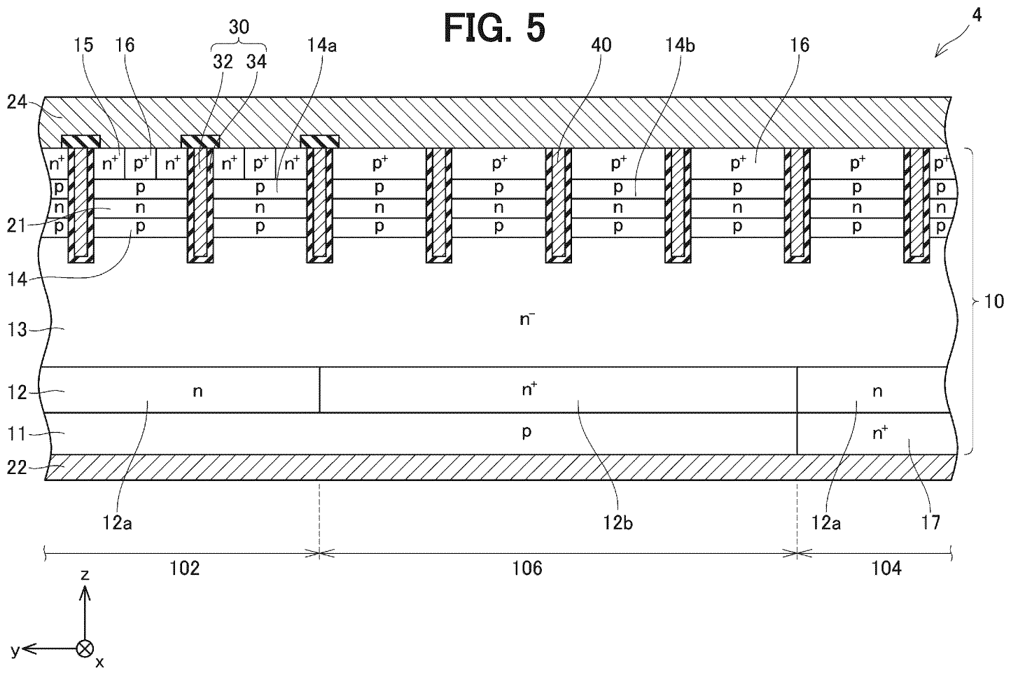

As shown in FIG. 5, in a semiconductor device 4, an n-type barrier layer 21 is provided in the semiconductor substrate 10. The barrier layer 21 is provided across the IGBT region 102, the boundary region 106, and the diode region 104 of the semiconductor substrate 10. The barrier layer 21 is embedded in the base layer 14 and divides the base layer 14 into upper and lower parts. The barrier layer 21 is formed by ion-implanting n-type impurity toward the upper surface of the semiconductor substrate 10 using an ion implantation technique. The n-type impurity is not particularly limited, but may be, for example, phosphorus. The effective peak concentration of the n-type impurity in the barrier layer 21 may be lower than the effective peak concentration of the p-type impurity in the second base layer 14b. When the barrier layer 21 is provided, hole injection from the base layer 14 can be suppressed during recovery operation. Therefore, the semiconductor device 4 can have low recovery loss characteristics.

Although specific examples of the present disclosure have been described in detail above, these are merely examples and do not limit the scope of claims. The techniques described in the claims include various modifications and modifications of the specific examples illustrated above. In addition, the technical elements described in the present description or the drawings exhibit technical usefulness alone or in various combinations, and are not limited to the combinations described in the claims at the time of filing. In addition, the techniques illustrated in the present specification or drawings can achieve multiple purposes at the same time, and achieving one of the purposes itself has technical usefulness.

What is claimed is:

1. A reverse conducting IGBT comprising:
a semiconductor substrate having an IGBT region, a diode region, and a boundary region located between the IGBT region and the diode region;
a lower electrode provided on a lower surface of the semiconductor substrate; and
an upper electrode provided on an upper surface of the semiconductor substrate, wherein
the semiconductor substrate includes:
a drift layer of a first conductivity type provided across the IGBT region, the diode region, and the boundary region;
a base layer of a second conductivity type provided across the IGBT region, the diode region, and the boundary region and disposed above the drift layer;
an emitter layer of a first conductivity type provided in the IGBT region and disposed above the base layer to be in contact with the upper electrode;
a collector layer of a second conductivity type provided in the IGBT region and the boundary region and disposed below the drift layer to be in contact with the lower electrode;
a cathode layer of a first conductivity type provided in the diode region and disposed below the drift layer to be in contact with the lower electrode; and
a buffer layer of a first conductivity type disposed between the collector layer and the drift layer, the buffer layer having a higher concentration of first conductivity type impurity than a concentration of first conductivity type impurity in the drift layer,
the buffer layer has a first buffer layer provided in the IGBT region and a second buffer layer provided in the boundary region, and
a peak concentration of the first conductivity type impurity in the second buffer layer is higher than a peak concentration of the first conductivity type impurity in the first buffer layer.

2. The reverse conducting IGBT according to claim 1, wherein
the buffer layer further has a third buffer layer provided in the IGBT region at a vicinity of the boundary between the IGBT region and the boundary region, and
a peak concentration of the first conductivity type impurity in the third buffer layer is higher than a peak concentration of the first conductivity type impurity in the first buffer layer.

3. The reverse conducting IGBT according to claim 2, wherein the second buffer layer and the third buffer layer are adjacent to each other at a boundary between the IGBT region and the boundary region.

4. The reverse conducting IGBT according to claim 1, wherein a peak concentration of the first conductivity type impurity in the second buffer layer is lower than a peak concentration of the second conductivity type impurity in the collector layer.

5. The reverse conducting IGBT according to claim 1, wherein the buffer layer is disposed between the cathode layer and the drift layer.

6. The reverse conducting IGBT according to claim 1, wherein
the base layer has a first base layer provided in the IGBT region and a second base layer provided in the diode region and the boundary region, and
a concentration of the second conductive type impurity in the second base layer is lower than a concentration of the second conductive type impurity in the first base layer.

7. The reverse conducting IGBT according to claim 1, wherein the semiconductor substrate further includes a barrier layer of a first conductivity type provided across the IGBT region, the diode region and the boundary region and embedded in the base layer.

8. The reverse conducting IGBT according to claim 1, further comprising a trench gate provided in the IGBT region, wherein the trench gate is arranged in a trench extending from an upper surface of the semiconductor substrate through the base layer to the drift layer.

9. The reverse conducting IGBT according to claim 1, further comprising a dummy trench gate provided in the diode region and the boundary region, wherein the dummy trench gate is provided in a trench extending from the upper surface of the semiconductor substrate through the base layer to reach the drift layer.
